(19) United States
(12) Patent Application Publication
(10) Pub. No.: US 2006/0222024 A1
(43) Pub. Date: Oct. 5, 2006

(54) Mode-locked semiconductor lasers with quantum-confined active region

(76) Inventors: Allen L. Gray, Albuquerque, NM (US); Hua Huang, Albuquerque, NM (US); Hua Li, Albuquerque, NM (US); Petros M. Varangis, Albuquerque, NM (US); Lei Zhang, Albuquerque, NM (US); John L. Zilko, Albuquerque, NM (US)

Correspondence Address: FENWICK & WEST LLP, SILICON VALLEY CENTER, 801 CALIFORNIA STREET, MOUNTAIN VIEW, CA, 94041, US

(21) Appl. No.: 11/302,724

(22) Filed: Dec. 13, 2005

Related U.S. Application Data
(60) Provisional application No. 60/662,451, filed on Mar. 15, 2005.
(60) Provisional application No. 60/723,412, filed on Oct. 3, 2005.

(51) Int. Cl. H01S 3/098; H01S 5/00

(52) U.S. Cl. 372/18; 372/45.013

(57) ABSTRACT

A mode-locked integrated semiconductor laser has a gain section and an absorption section that are based on quantum-confined active regions. The optical mode(s) in each section can be modeled as occupying a certain cross-sectional area, referred to as the mode cross-section. The mode cross-section in the absorber section is larger in area than the mode cross-section in the gain section, thus reducing the optical power density in the absorber section relative to the gain section. This, in turn, delays saturation of the absorber section until higher optical powers, thus increasing the peak power output of the laser.

### CROSS-REFERENCE TO RELATED APPLICATION(S)

This application claims priority under 35 U.S.C. § 119(e) to U.S. Provisional Patent Application Ser. No. 60/662,451, “High Power and Wide Operating Temperature Range Mode-Locked Semiconductor Lasers,” filed Mar. 15, 2005; and under U.S. Provisional Patent Application Ser. No. 60/723,412, “High Power Mode-Locked Semiconductor Lasers,” filed Oct. 3, 2005. The subject matter of all of the foregoing is incorporated herein by reference in their entirety.

### BACKGROUND OF THE INVENTION

1. Field of the Invention

This invention relates to mode-locked semiconductor lasers with a quantum-confined active region. 2. Description of the Related Art

Laser mode-locking is a technique of generating optical pulses by modulation of a resonant laser cavity. The laser cavity includes a light-amplifying gain section, where population inversion and positive optical feedback take place. The laser cavity may also include an absorber section, where optical loss takes place. Modulation of the gain and/or loss in these sections (typically referred to as “loss modulation” regardless of whether gain or loss is modulated) causes the laser light to collect in short pulses located around the point of minimum loss. The pulses typically have a pulse-to-pulse spacing given by the cavity round-trip time T_{R}=2L/v_{g}, where L is the length of the laser cavity (assuming a linear cavity) and v_{g} is the group or propagation velocity of the peak of the pulse intensity inside the laser cavity.

For monolithic semiconductor lasers, two parallel and partly transparent mirrors can be made by cleaving the semiconductor along its crystallographic planes, thus forming a Fabry-Perot laser cavity. Optical gain can be created by pumping (either electrically or optically) an active region within the laser cavity. Active regions can be based on conventional doped p-n junctions. Alternately, active regions can be based on quantum-confined structures, such as quantum wells, quantum wires and quantum dots. Quantum-confined active regions have certain performance advantages over more conventional p-n junction active regions. However, in quantum-confined mode-locked semiconductor lasers, mode-locking typically occurs for values of the pump current that are close to its threshold value. This limits the maximum peak power that can be achieved which, in turn, limits the possible applications for these devices.

Thus, there is a need for quantum-confined mode-locked semiconductor lasers that can achieve higher peak powers.

### SUMMARY OF THE INVENTION

The present invention overcomes the limitations of the prior art by providing a quantum-confined mode-locked semiconductor laser in which the “mode size” of an absorption region in the laser cavity is increased relative to the mode size of the gain region in the laser cavity. In more detail, the semiconductor laser includes a laser cavity with an optical path. A gain section and an absorber section are located along the optical path and produce loss modulation leading to the mode-locked behavior. The gain section and/or the absorber section contain a quantum-confined active region. The mode volume of the absorber section is increased (e.g., in length and/or cross-sectional area), thus reducing the optical power density in the absorber section. This, in turn, delays saturation of the absorber section until higher optical powers, thus increasing the peak power that can be output by the laser.

In one design, the semiconductor laser includes a horizontal laser cavity integrated on a semiconductor substrate. For example, the laser cavity may be formed by cleaving two ends of a semiconductor structure to form two parallel planar mirrors. The mirrors may optionally be coated to achieve the desired reflectivity. A quantum-confined active region is located along the optical path of the laser cavity. For example, various epitaxial layers may be grown on the substrate to form the quantum-confined active region. One section of the quantum-confined active region is used as part of the gain section, for example by forward biasing that section of the quantum-confined active region. A different section of the quantum-confined active region is used as part of the absorber section, for example by reverse biasing this section.

The gain section and absorber section are designed so that the mode cross-section of the absorber section has a larger area than the mode cross-section of the gain section. In one particular design, the optical mode is laterally confined by a ridge waveguide, which has a narrower width in the gain section and flares out to a broader width in the absorber section. Other waveguide designs can also expand in width to achieve a greater mode cross-section in the absorber section than in the gain section. The mode cross-section can also be expanded in the vertical direction, for example by changing the size, spacing and/or composition of the layers in the absorber section compared to the gain section.

The principles described above can be applied to both actively and passively mode-locked lasers. In one class of passively mode-locked lasers, the gain and absorber sections are DC biased and the saturation of the quantum-confined active region in the absorber section creates the loss modulation that leads to mode-locking. In one class of actively mode-locked lasers, a periodically modulated electrical signal is applied to the gain section and/or the absorber section, thus creating the loss modulation.

The quantum-confined active region itself can have different structures. Quantum wells, wire and dots are examples of quantum-confined structures suitable for use in active regions. Quantum dots are generally preferred due to their singular, delta-function like density of states. In one design, the semiconductor substrate is a GaAs substrate, and the quantum-confined active region is based on self-assembled InAs quantum dots in InGaAs quantum wells.

Other aspects of the invention include products based on the structures described above, applications for these structures and products, and methods for using and fabricating all of the foregoing.

### BRIEF DESCRIPTION OF THE DRAWINGS

The invention has other advantages and features which will be more readily apparent from the following detailed description of the invention and the appended claims, when taken in conjunction with the accompanying drawings, in which:

FIG. 1 is a perspective diagram of a mode-locked semiconductor laser according to the present invention.

FIG. 2 is a side cross-section of a three-section actively mode-locked semiconductor laser.

FIG. 3 is a side cross-section of a two-section passively mode-locked semiconductor laser.

FIG. 4 is a top view of a mode-locked semiconductor laser using a tapered ridge waveguide.

FIG. 5 is a schematic of the distribution of the optical field in the laser waveguide and cladding layer.

FIGS. 6A-6E are diagrams of epitaxial layer designs for different semiconductor mode-locked lasers.

The figures depict embodiments of the present invention for purposes of illustration only. One skilled in the art will readily recognize from the following discussion that alternative embodiments of the structures and methods illustrated herein may be employed without departing from the principles of the invention described herein.

### DETAILED DESCRIPTION OF THE PREFERRED EMBODIMENTS

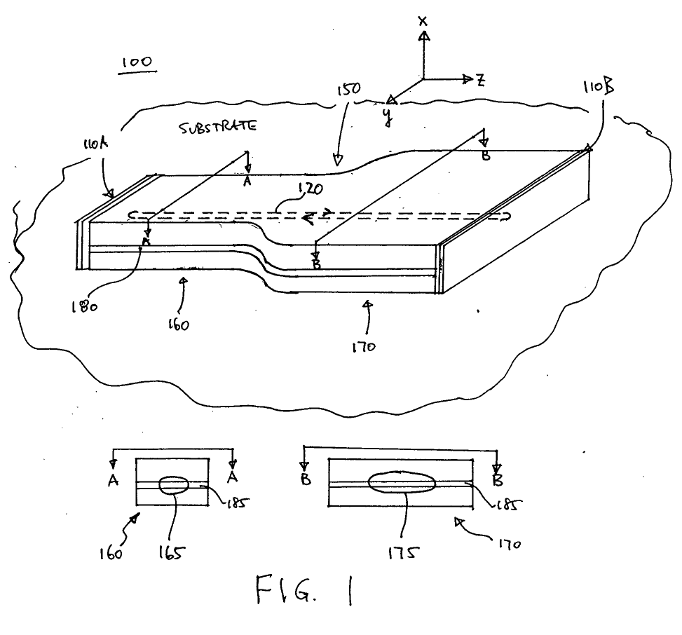

FIG. 1 is a diagram of an integrated mode-locked semiconductor laser 100 according to the present invention. The laser structure 100 is integrated onto the underlying substrate. For example, it may be fabricated by epitaxially depositing different layers of material onto the substrate. Alternately, it may be fabricated by doping various regions of the substrate. Etching and lithography are two common processes that may be used to fabricate the integrated laser structure 100 on the semiconductor substrate.

The laser 100 has a horizontal laser cavity 150. In this example, the laser cavity 150 is a linear cavity defined by two planar end mirrors 110A and 110B. The optical path 120 through the laser cavity 150 is the round-trip path between the two mirrors 110.

For convenience, throughout this application, the x-y-z coordinate system will be defmed with z being the direction of propagation along the optical path 120, y being perpendicular to the optical path 120 but parallel to the substrate surface, and x being perpendicular to the substrate surface. The coordinate system is defined locally for each point along the optical path. The y and z directions may change if the optical path is not linear. Terms such as “up,” “down” and “vertical” refer to the x direction (i.e., generally perpendicular to the substrate surface), “lateral” refers to the y direction, and “horizontal” generally means parallel to the substrate surface. “Transverse,” when referring to the optical mode or optical propagation, refers to the x and y directions, whereas “longitudinal” refers to the z direction. “Height” or “thickness,” “width,” and “length” refer to quantities along the x, y, and z directions, respectively.

The laser 100 also includes a gain section 160 and an absorber section 170 located along the optical path 120. At least one of the gain section 160 and the absorber section 170 also includes a quantum-confined active region 180, such as quantum well layers, quantum wires and/or quantum dots. Quantum wells are structures having energy barriers that provide quantum confinement of electrons and holes in one dimension, which is selected to be less than the room temperature thermal de Broglie wavelength. Quantum wires have energy barriers that provide quantum confinement of electrons and holes in two dimensions, which are selected so that each one is less than the room temperature thermal de Broglie wavelength. Quantum dots have energy barriers that provide quantum confinement of electrons and holes in all three dimensions, which are selected so that each one is less than the room temperature thermal de Broglie wavelength. Combinations of these structures can also be used. For an electrically activated, quantum-confined gain section 160, electrical energy is input to the quantum-confined active region 180, which then amplifies light propagating through the active region. For an electrically activated, quantum-confined absorber section 170, energy from light propagating through the quantum-confined active region 180 is converted from optical to electrical form, thus introducing an optical loss in the optical path.

The gain section 160 and/or absorber section 170 introduce a loss modulation to light propagating around the laser cavity, resulting in the collection of light into pulses that are emitted by the laser 100 through one of the end mirrors 110. Various examples of loss modulation are discussed in further detail below.

The two end mirrors 110 help determine the longitudinal optical characteristics of the laser cavity 150. The transverse characteristics of the laser cavity 150 typically are determined by waveguiding structures that help to laterally confine the light in both the x and y directions as the light propagates around the laser cavity. The waveguiding structures can vary along the optical path, thus producing different transverse optical confinement at different locations in the laser cavity. Different waveguide designs at different points along the optical path can support different transverse optical modes.

FIG. 1 shows cross-sections A-A and B-B of the laser cavity within the gain section 160 and the absorber section 170, respectively. The ovals 165 and 175 shown in these cross-sections are a measure of the transverse optical confinement at each of these cross-sections and will be referred to as the mode cross-section. In one definition, the mode cross-section is defined by the contour where the intensity is equal to 1/e times the peak intensity of the optical mode at that cross-section (i.e., the “near field”). The mode cross-sectional area is the area within the contour, where the intensity is greater than the 1/e intensity. The mode cross-section may include two or more disjoint areas, depending on the intensity distribution of the optical mode.

In FIG. 1, the mode cross-section 175 of the absorber section 170 has a larger area than the mode cross-section 165 of the gain section 160. For a laser pulse of a given power, the optical power density (i.e., optical power divided by the area of the mode cross-section) will be reduced compared to an absorber section 170 that has the same mode cross-section 165 as the gain section 160. As a result, the absorber section 170 with larger mode cross-sectional area will not saturate until higher pulse powers are reached, thus allowing the laser to output higher power pulses.

Monolithic mode-locked semiconductor lasers such as shown in FIG. 1 offer significant advantages compared to other types of mode-locked lasers (e.g., solid state mode-locked lasers, such as Ti:sapphire or Nd:glass lasers) due to their compact size, inherent reliability and suitability to be produced in significant volumes by employing commercial high-yield manufacturing processes. They are strong candidates for applications requiring a low-cost reliable source of multi-GHz optical pulses to address high-volume consumer applications, such as processor-to-processor and on-processor optical clock distribution. Various embodiments of these lasers can exhibit high output optical power and stable performance in terms of pulsewidth, rms timing jitter, emission wavelength, and pulse repetition frequency, often across a wide operating temperature range.

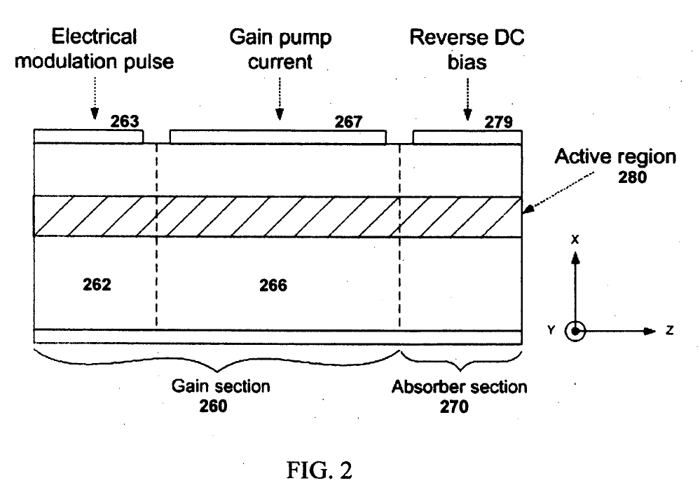

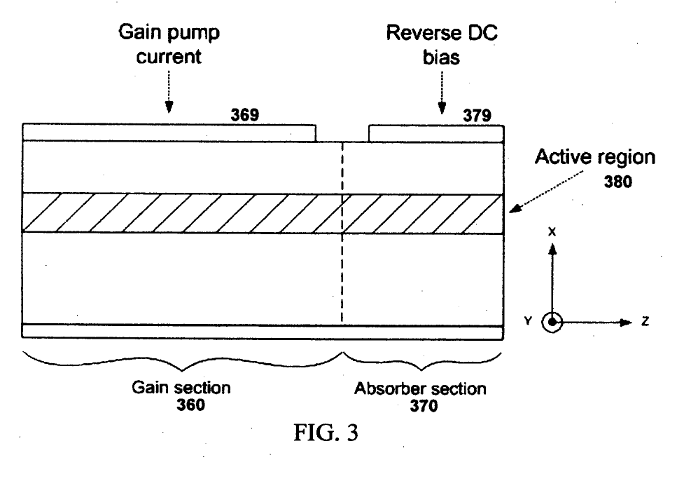

FIGS. 2-3 are diagrams that illustrate different types of mode-locking. FIG. 2 shows a three-section actively mode-locked semiconductor laser. The laser in FIG. 2 has a gain section 260 and an absorber section 270. The gain section 260 itself has two sections 262 and 266. A common quantum-confined active region 280 runs through all three sections. Electrical contacts 263, 267 and 279 make the electrical connections to each of the three sections. The first gain section 262 is driven by an electrical modulation pulse that has a frequency which is an integral multiple of the inverse of the cavity round-trip time. That is, if the cavity round trip time is T_{R}, then the period of the electrical modulation pulse is T_{R}/J for an integer J, which may be one. In this way, each point of the light beam propagating around the laser cavity experiences the same gain and absorption on each round trip, even though that gain and absorption may be different from one point of the light beam to the next. This creates the loss modulation (in this case, an active modulation of the gain section) that leads to mode-locking and pulse generation. The second gain section 267 is forward biased with a DC current to provide steady gain for the device. The saturable absorption region 279 is reverse-biased. Other methods of active mode-locking may also be used. For example, electrical modulation may be applied to the absorber section instead of, or in synchronization with, the gain section.

In one class of actively mode-locked lasers, an electronically driven loss modulation produces a sinusoidal loss modulation with a period given by the cavity round trip time T_{R}. The saturated gain at steady state supports net gain around the minimum of the loss modulation and therefore supports pulses that are significantly shorter than the cavity round trip time.

FIG. 3 is a schematic diagram of a two-section passively mode-locked semiconductor laser. In this example, the gain section 360 is forward biased with a DC current to provide the overall gain for the device and the saturable absorption region 370 is reverse-biased. The saturable absorber is used to obtain a self-amplitude modulation of light inside the laser cavity. The saturable absorber introduces a loss that is a larger percentage loss for low intensity light but a lower percentage loss for higher intensity light due to saturation of the absorption process. Thus, a short pulse produces a loss modulation, because the high intensity at the peak of the pulse saturates the absorber more strongly than its low intensity wings. The loss modulation typically exhibits fast initial loss saturation (i.e. reduction of loss) determined by the pulse duration and typically a somewhat slower recovery depending on the detailed mechanism of carrier dynamics in the saturable absorber and the applied reverse bias in the absorption section.

The saturable absorbers currently used in semiconductor lasers typically exhibit an absorption recovery time on the order of a few tens of ps. E.g., see D. J. Derickson et. al., “Short Pulse Generation Using Multisegment Mode-Locked Semiconductor Lasers,” IEEE Journal of Quantum Electronics, Vol. 28 (10), pp. 2186-2202 (1992). This fast recovery time results in a fast loss modulation, which in turn generally allows shorter pulses. Additionally, because the absorption recovery time limits the achievable repetition rate in a passively mode-locked laser, an absorption recovery time on the order of a few tens of ps implies that a pulse repetition frequency on the order of 100 GHz is possible. Experimentally, monolithic semiconductor lasers have been passively mode-locked with repetition rates of 350 GHz. E.g., see Y. K. Chen, et. al., “Subpicosecond monolithic colliding pulse mode-locked multiple quantum well lasers,” Applied Physics Letters, Vol. 58, pp. 1253-1255 (1991).

The absorption of the saturable absorber preferably saturates at a lower energy than the gain of the gain medium. The saturation energy of a material is defined as:
Eₛₐₜ=hνA/(∂g/∂N), (1)
where h is the Plank's constant, ν is the optical frequency, A is the mode cross-sectional area inside the laser cavity, and ∂g/∂N is the differential gain with respect to carrier density. The saturation energy is a measure of the energy required to saturate the gain of the gain section or the absorption of the absorber section. In semiconductor laser materials, the slope of the gain versus carrier density function typically decreases in value as the carrier density level is increased. E.g., see G. P. Agrawal and N. K. Dutta, Semiconductor Lasers, New York, Van Nostrand Reinhold, 1993. Because the carrier density level in saturable absorbers is smaller than in gain regions, semiconductor saturable absorbers typically have lower saturation energies than semiconductor gain regions.

Furthermore, in analysis conducted by and results obtained by the inventors, it appears that in mode-locked semiconductor lasers with straight ridge waveguides the mode-locked peak power is limited primarily by the size of the absorber section. In order to generate mode-locked laser pulses with narrow pulse width and high peak power, two design considerations are preferably followed. First, the saturation energy of the absorber section preferably should be lower than the saturation energy of the gain section, based on the definition of Eqn. 1. This is typically the case in semiconductor lasers as described above. Second, the maximum achievable mode-locked peak power is typically proportional to the power required to saturate the absorption of the absorber section and obtain maximum carrier inversion.

Therefore, generally speaking, when the size of the absorber section is increased, more power is required to saturate the absorption in the absorber section. This, in turn, will extend the mode-locking regime to larger values of the gain section pump current with correspondingly higher output power. Put in another way, increasing the volume of the optical mode (i.e., the mode volume), and correspondingly decreasing the photon density, in the absorber section generally means that more power will be required to saturate the absorption in the absorber section and realize efficient mode-locking. This will extend the mode-locking regime to larger values of the gain section pump current with correspondingly higher output optical power.

In one approach, the mode volume of the absorber section is increased by increasing the length of the absorber section. However, there is a limit to this approach, the preferred acceptable length of the absorber section that leads to efficient mode-locking depends on the particular technical specifications such as target pulse duration, pulse repetition rate, and the mechanism of the absorption process in the saturable absorber (e.g. carrier recovery time). Under conditions of strong excitation, the absorption in the absorber section is typically saturated because the initial carrier states in the valence band are depleted while the final carrier states in the conduction band are partially occupied. Within a sub-ps timescale after the excitation, the carriers in each band thermalize and this leads to a partial recovery of the absorption. On a longer time scale, typically a few ps to a few tens of ps in semiconductor materials, the carriers will be removed by recombination and trapping, and absorption will recover. Therefore, if the length of the absorber section exceeds a certain limit, the pulse will be re-absorbed strongly and mode-locking will be destroyed or the mode-locking characteristics of the pulse will be degraded.

Therefore, the length of the absorber section typically is bounded by various requirements. The absorber section generally cannot be shorter than a certain length because a minimum level of absorption is required in order to achieve mode locking with an acceptably narrow pulse width. The maximum acceptable pulse width typically is set by the requirements of the particular application. In addition, various factors may limit the maximum length of the absorber section. First, the absorption saturation energy in the absorber section must be less than the gain saturation energy in the gain section, thus limiting the maximum length of the absorber section. Second, the absorber section cannot be too long or the recovery of absorption may cause the laser to exceed limits for certain characteristics of the laser pulse, such as pulse width and jitter. Therefore the optimum length of the absorber section is bounded by these upper and lower limits, although the specific values for these upper and lower limits depend on the requirements for the particular application (e.g. pulse width) and on the design of the laser epi structure (which determines the gain, etc).

The design of the absorber section can be optimized not only in length (i.e., along the z dimension), by selecting the appropriate ratio of the length of the gain section to the length of the absorber section, but also along one or more transverse dimensions, such as along the lateral y dimension and/or the vertical x dimension.

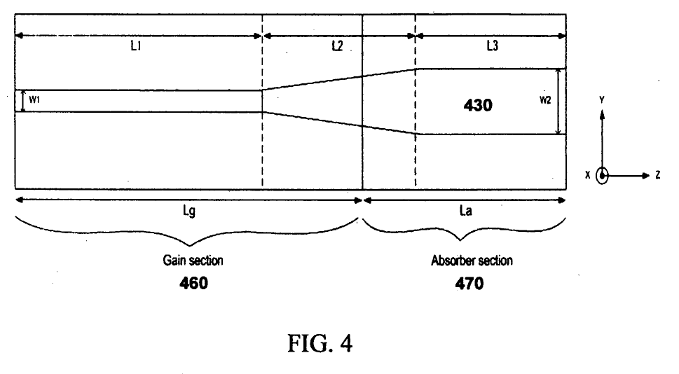

FIG. 4 is a top view of a mode-locked semiconductor laser illustrating one example of this approach. In this example, a ridge waveguide 430 is used for lateral optical confinement (i.e., in the y direction) and the design of the epitaxial layers used to form the laser are used for vertical optical confinement (i.e., in the x direction). The ridge waveguide 430 is tapered, increasing to a larger width in the absorber section 470. If all else is equal, the mode cross-section of the absorber section 470 will be wider and have a greater area than that of the gain section 460.

In more detail, the parameters L_{g} and Lₐ denote the length of the gain and absorber section, respectively. In the lateral direction, the ridge waveguide 430 has three sections: a straight ridge waveguide section of width w₁, and length L₁, a straight ridge waveguide section of width w₂, (with w₂>w₁) and length L₃, and a flared or tapered waveguide section of length L₂ connecting the two straight ridge waveguide sections and tapering from the narrow straight waveguide (of width w₁) towards the wider ridge waveguide (of width w₂). The tapered waveguide section is flared towards the absorber section 470 of the mode-locked laser. In this example, the laser pulses are output through the output facet of the gain section (i.e., the lefthand side of the structure.

The boundary between the gain section 460 and absorber section 470 of the mode-locked laser may be located anywhere within the three waveguide sections. In FIG. 4, the boundary between the gain and absorber sections is shown as occurring in the middle waveguide section. The device layout is designed so that when w₂>w₁, the mode width of the absorber section is larger than the mode width of the gain section, which in turn increases the power required to saturate the absorption in the absorber section (compared to the case when W₂=w₁) and therefore will extend the mode-locking regime to larger values of the gain section pump current and in turn result in higher output optical power. The upper limit to the width of the waveguide in the absorber section typically is set by the requirement on the optical mode to retain good spatial coherence and to avoid filamentation.

In the vertical x direction, increases in the peak mode-locked power can be similarly achieved by increasing the height of the mode cross-section. For epitaxially grown devices, this can be achieved by the design (thickness, composition, doping level etc.) of waveguiding and/or cladding layers so as to expand the optical mode in the vertical direction. Increased mode height can increase the power required to saturate the absorption in the absorber section and therefore can extend the mode-locking regime to larger values of the gain section pump current and in turn result in higher output optical power, whereas at the same time maintaining the desired optical pulse characteristics, such as jitter and pulse width. The peak mode-locked power can be improved further increasing in the mode cross-sectional area in both the lateral and vertical directions.

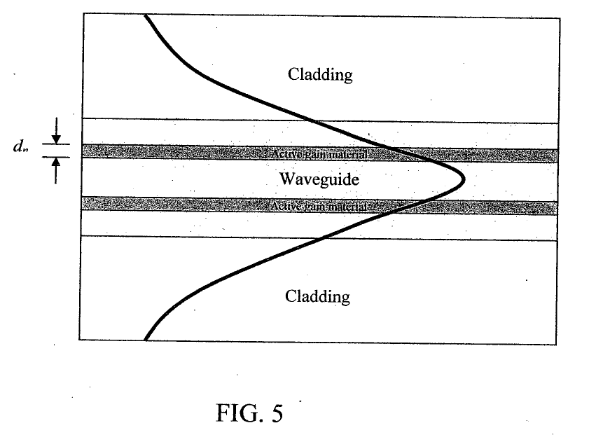

Increasing the mode cross-sectional area preferably is done while taking account of other design factors. For example, the optical confinement factor Γ and modal gain (gₘ=Γg₀, where g₀ is the material gain) should be maintained at levels sufficient to support lasing. The optical confinement factor is defined as the overlap of optical field and the active gain material (whether bulk semiconductor, quantum well, quantum wire, or quantum dot) and is given by

$$Γ = \frac{\sum {\int }_{{x}_{n} - {d}_{n} / 2}^{{x}_{n} + {d}_{n} / 2} {Ψ}^{*} ( x , y ) \cdot Ψ ( x , y ) ⅆ x ⅆ y}{{\int }_{- ∞}^{∞} {Ψ}^{*} ( x , y ) \cdot Ψ ( x , y ) ⅆ x ⅆ y} \qquad ( 2 )$$

where xₙ, dₙ denote the center position and the thickness of the n^{th} layer of the active gain material as shown in FIG. 5, the summation of the top term is over all layers with active gain materials, and Ψ(x, y) is the wavefunction of the optical field. In the configuration of FIG. 5, the optical field distribution is determined mainly by the index of the cladding layers, the index of the waveguide, and the height of the waveguide. For example, the expansion of the optical field in the vertical direction can be achieved by reducing the difference in the refractive indices of the cladding and waveguide layers or by reducing the height of the waveguide layer. As the optical field expands, the confinement factor θ and the modal gain (gₘ=θg₀) decrease. The lasing condition, (θg_{0-α})*L=0 sets a limit for the optical field expansion, where α denotes the total losses of the laser including waveguide and mirror losses. Increasing material gain and reducing internal loss and waveguide loss enable further expansion of the optical field and therefore higher mode-locked peak power.

Different types of quantum-confined active regions can be used, including quantum wells, quantum wires and quantum dots. However, in contrast to quantum wells, where carriers are localized and confined in one dimension, and quantum wires, where carriers are localized in two dimensions, quantum dots confine the electrons or holes in all three dimensions and, thus, exhibit a discrete energy spectrum. Such three-dimensional carrier confinement, which leads to singular, delta-function like, density of states, sharp electronic transitions and a pure optical spectrum, result in certain advantages for quantum dot mode-locked lasers compared even to quantum well and quantum wire mode-locked lasers.

For example, passively mode-locked quantum dot lasers can exhibit low rms timing jitter, which can eliminate the need for more expensive and complicated active or hybrid mode-locking schemes. The timing jitter in passively mode-locked lasers typically arises from fluctuations in the carrier density, photon density, and index of refraction caused by amplified spontaneous emission. Due to the discrete energy levels and low transparency current in a quantum dot active gain region, the portion of carriers involved in non-stimulated emission is significantly reduced, resulting in a low value of the linewidth enhancement factor and in turn low timing jitter.

The linewidth enhancement factor a describes the degree to which variations in the carrier density N alter the index of refraction n of an active layer for a particular gain g at the lasing wavelength λ. The linewidth enhancement factor can be mathematically expressed as:
α=(4π/λ)[(dn/dN)/(dg/dN)] (3)
Experiments indicate that the linewidth enhancement factor of quantum dot lasers can reach 0.1, which is almost twenty times lower than for comparable quantum well lasers (e.g., see T. C. Newell et. al., “Gain and linewidth enhancement factor in InAs quantum dot laser diodes,” IEEE Photonics Technology Letters, Vol. 11(12), pp. 1527-1529 (1999)), as further described in U.S. Pat. No. 6,816,525, “Quantum Dot Lasers,” which is incorporated herein by reference. The low linewidth enhancement factor correspondingly reduces the rms timing jitter exhibited by the quantum dot mode-locked lasers. Operation of passively mode-locked quantum dot lasers that exhibit rms timing jitter less than 1 ps at a 5-GHz pulse repetition rate has been demonstrated. See L. Zhang, et. al., “Low timing jitter, 5 GHz optical pulses from monolithic two-section passively mode-locked 1250/1310 nm quantum dot lasers for high speed optical interconnects,” Paper OWM4, OFC/NFOEC 2005 Technical Conference, Mar. 6-11, 2005, Anaheim, Calif. USA. This is more than one order of magnitude lower than the rms timing jitter exhibited by comparable quantum well lasers.

Quantum dot mode-locked lasers can also exhibit insensitivity to external spurious feedback, generated, for example, by coupling light from the laser into a fiber. Such insensitivity to external feedback can be important when packaging the devices because it eliminates the need for expensive sub-components, such as optical isolators.

Quantum dot mode-locked lasers can also exhibit improved performance in terms of threshold current and power slope efficiency across a wide operating temperature range (e.g., 0° C. to 125° C.), for example through optimization of the structural properties of the quantum dots, specifically the dot size uniformity or through the introduction of modulation p-type doping in the active region. E.g., see D. G. Deppe, et. al., “Modulation characteristics of quantum dot lasers: the influence of p-type doping and the electronic density of states on obtaining high speed,” IEEE Journal of Quantum Electronics, Vol. 38(12), pp. 1587-1593 (2002); and K. Mukai, et. al., “High characteristic temperature of near 1.3-micron InGaAs/GaAs quantum dot lasers at room temperature,” Applied Physics Letters, Vol. 76(23), pp. 3349-3351 (2000).

Quantum dot lasers can also exhibit low internal losses α_{I}, (not to be confused with the linewidth enhancement factor α of Eqn. 3). This is important in order to obtain low-jitter, high optical power passively mode-locked lasers. Internal losses in semiconductor lasers are primarily contributed by free carriers absorbed in the laser waveguide regions. In quantum dot lasers, such as those described in U.S. Pat. No. 6,816,525, “Quantum Dot Lasers,” as the localization of the active region gets deeper, due to the incorporation of the quantum dots inside a quantum well, the free carrier population in the GaAs matrix (i.e., the waveguide layer) is reduced, leading to a corresponding reduction in internal losses.

Additionally, an important manufacturing advantage is the fact that quantum dot mode-locked lasers emitting within the 1060-1340 nm wavelength range can be grown on GaAs substrates, which leads to significantly higher manufacturing yields compared to quantum well lasers emitting within the similar wavelength range but grown instead on InP substrates.

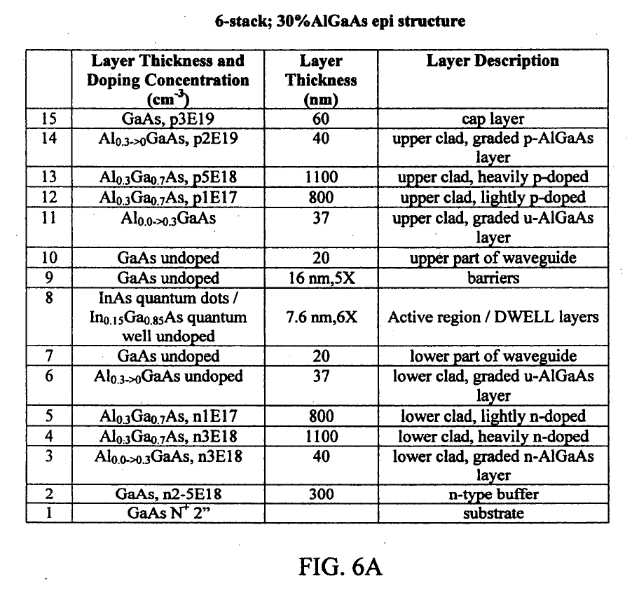

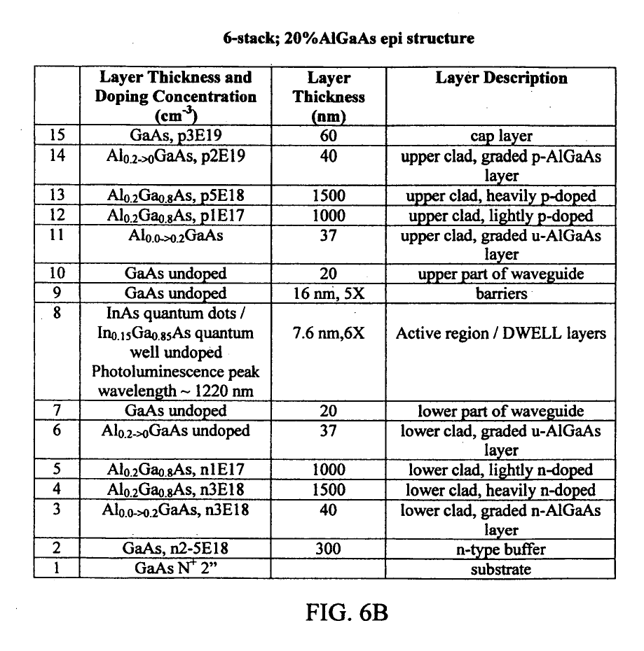

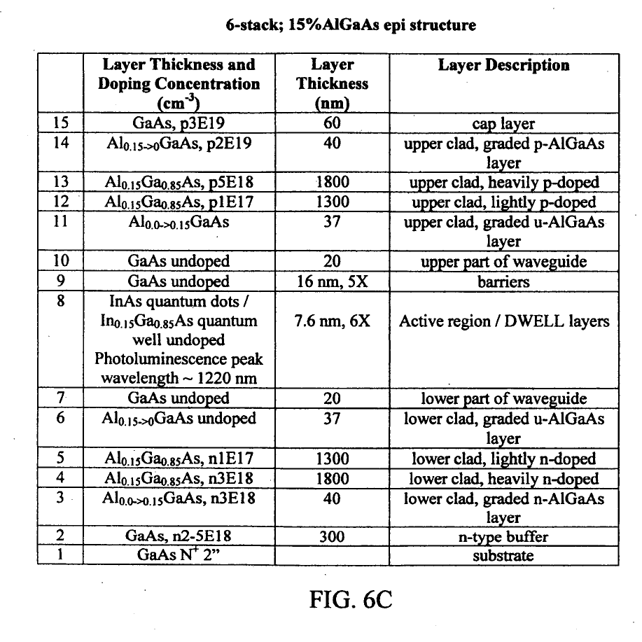

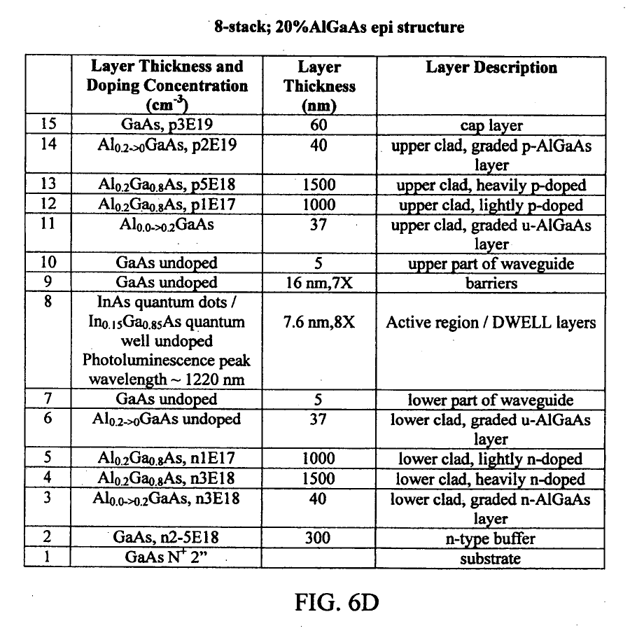

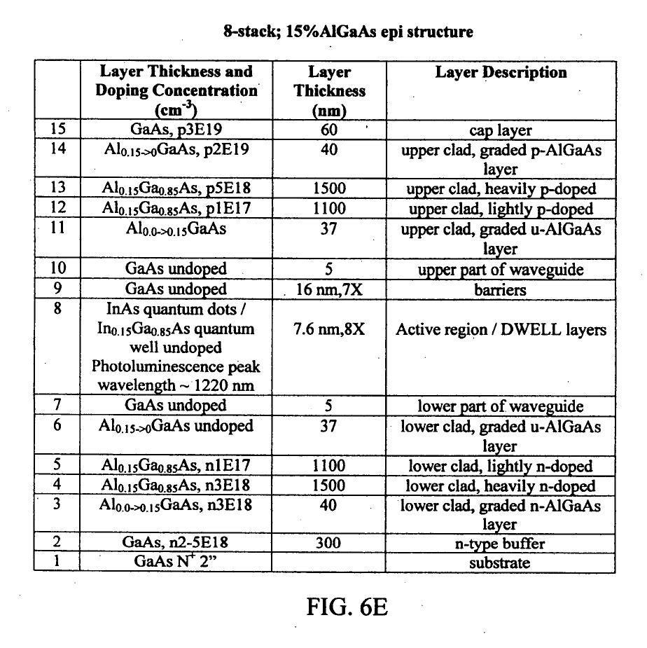

FIGS. 6A-6E show the epitaxial structures of selected embodiments of quantum dot passively mode-locked lasers. These lasers under passive mode-locking operation have demonstrated high peak mode-locked power (larger than 1 W), low timing jitter (less than 10 fs pulse-to-pulse jitter), and narrow pulses (less than 10 ps pulse width) across the 30-60° C. temperature range. In certain designs, the length of the absorber section is between 1/20 to ⅕ of the total length of the laser cavity, the width of the waveguide of the absorber section varies between 3 and 11 μm, and the ratio of the width of the waveguide in the absorber section to the width of the waveguide in the gain section varies between 1:1 and 4:1. The total length of the laser cavity is determined in part by the pulse repetition rate. For a pulse repetition rate with period T_{P}, the cavity round trip time preferably is T_{R}=J T_{P} where J is a non-zero integer. The cavity round trip time is, in turn, determined by the total length of the laser cavity. For certain applications, the mode-locked laser is designed for a pulse repetition rate of between 5-100 GHz.

The epitaxial structures shown can be used in a number of structures with different vertical and lateral characteristics. In one approach, the layers are epitaxially grown on the substrate and then laterally patterned by subsequent etching, resulting in a mesa structure as shown in FIG. 1. In a different design, the layers are epitaxially grown but they are not laterally patterned. Rather, they remain buried. Lateral confinement of the optical mode can be achieved by etching isolation trenches, doping to achieve optical confinement or by use of a ridge waveguide (as shown in FIG. 4.)

The active region in these examples is self-assembled InAs quantum dots formed in InGaAs quantum wells that are grown on a GaAs substrate by molecular beam epitaxy, based on epitaxial growth techniques and designs as described in U.S. Pat. No. 6,816,525, “Quantum Dot Lasers,” which is incorporated herein by reference. In the case of an ideal quantum dot array, i.e. quantum dot structures having a delta-function-like density of states, the operating temperature will not significantly adversely affect the performance characteristics of a quantum dot mode-locked laser. One difference that distinguishes realistic lasers based on a self-organized quantum dot array from the ideal case is the inhomogeneous broadening of the energy levels due to the size fluctuation of quantum dots. The structural properties (i.e. shape, size and surface density) of self-assembled quantum dots formed via the Stranski-Krastonow method depend on the growth conditions, such as the growth temperature of the active region and surrounding semiconductor matrix (barriers, cladding layers), the composition of surrounding structures including the strain of the underlying quantum well, the design parameters of the active region (e.g. thickness of quantum wells and barriers), the material growth rates, and the arsenic overpressure among others.

In order to achieve a more uniform quantum dot size distribution within a stack and from stack-to-stack in quantum dot mode-locked lasers, the design of the epitaxial structure of the laser is preferably optimized for example through appropriate adjustment of the number of quantum dot stacks, the thickness of the quantum wells and the barrier layers in the laser active region.

FIG. 6A shows one embodiment of a laser epitaxial design which can be used for quantum dot passively mode-locked lasers based on the principles described above. It is an illustration of a growth sequence for a laser having six layers of InAs quantum dots grown within and surrounded by an In_{0.15}Ga_{0.85}As quantum well. The quantum well assists the quantum dots to capture and retain injected carriers due to the lower bandgap energy of the central quantum well layer compared with surrounding barrier layers. An n-type GaAs buffer layer (#2) is grown on a GaAs substrate (#1). An approximately two micron thick AlGaAs cladding layer (#3, 4, 5) is then grown. This is followed by graded AlGaAs layer (#6) and a GaAs waveguiding layer (#7), which are undoped to reduce absorption losses.

The quantum-confined active region is composed of six In_{0.15}Ga_{0.85}As quantum wells (#8) of approximately 7.6 nm thickness. Inside each quantum well, InAs quantum dots of an equivalent thickness equal to 2.4 monolayers have been grown, based on the techniques described in U.S. Pat. No. 6,816,525, “Quantum Dot Lasers,” which are incorporated herein by reference. The quantum wells are separated from each other by GaAs barriers (#9) of approximate thickness 16 nm. In one embodiment, following the growth of the quantum well and prior to the growth of the barrier, several monolayers of GaAs are grown, followed by a growth interruption step in which the substrate temperature is raised to approximately 580-610° C. The growth interruption step preferably lasts long enough to desorb excess segregated indium from the surface prior to commencing growth of the GaAs barrier layer.

After the growth of the last InGaAs quantum well is completed, a GaAs waveguiding layer (#10) and a graded AlGaAs layer (#11) are grown, both undoped. An approximately two micron thick upper AlGaAs cladding layer (#12, 13, 14) is then grown, followed by a GaAs cap layer (#15). An electrical contact makes contact with the cap layer.

Layers 7, 8, 9 and 10 form a waveguide core region having a higher refractive index than the surrounding AlGaAs cladding layers, with the upper cladding layer composed of layers 11, 12, 13, and 14 and the lower cladding layer composed of layers 3, 4, 5 and 6. Consequently, this structure confines the optical mode in the vertical direction. A fraction of the optical mode will be confined in the portion of the structure occupied by the quantum dots.

Confinement in the lateral direction can be achieved by a variety of approaches. For example, the structure shown in FIG. 6A can be grown as a mesa (e.g., see FIG. 1), resulting in lateral confinement of the optical mode. Alternately, the layers shown in FIG. 6A need not extend indefinitely in the lateral direction. The layers can be lithographically defined to have a finite lateral extent, and then surrounded by lower index materials to form a lateral waveguide structure. As a final example, a ridge can be added to the structure shown in FIG. 6A to produce a lateral waveguiding effect.

FIGS. 6B-6E show additional exemplary embodiments of laser epitaxial designs which can be used for either quantum dot passively mode-locked lasers or quantum dot actively mode-locked lasers. Electrically, the p-type layers, undoped layers and n-type layers form a p-i-n structure. While one substrate polarity is shown, the doping polarity of the layers may be reversed in other embodiments from what is shown in these exemplary embodiments.

The quantum well layers in the active region (#8) provide a means to improve carrier capture by the quantum dots and also serve to reduce thermionic emission of carriers out of the dots. In a quantum dot laser, the fill factor of quantum dots in an individual quantum dot layer is low, typically less than 10%, depending upon the dot density and mean dot size. Because the quantum dots are disposed within the quantum well, carriers captured by the well layer of the quantum well may be captured by the quantum dot, thereby increasing the effective fill factor of quantum dots. Additionally, the barrier layers of the quantum well serve to reduce thermionic emission out of quantum dots.

The generation of ultra-fast optical pulses from monolithic semiconductor lasers is attractive owing to the compact and efficient properties of these devices. Applications of these devices include but are not limited to optical time division multiplexing, photonic switching, electro-optic sampling, optical computing, optical clocking, applied nonlinear optics and other areas of ultrafast laser technology.

While particular embodiments and applications of the present invention have been illustrated and described, it is to be understood that the invention is not limited to the precise construction and components disclosed herein and that various modifications, changes and variations which will be apparent to those skilled in the art may be made in the arrangement, operation and details of the method and apparatus of the present invention disclosed herein without departing from the spirit and scope of the invention as defined in this description.

For example, while embodiments of the present invention have been discussed in detail with regards to quantum dot layers comprising InAs embedded in InGaAs quantum wells, this invention may be practiced in other compound semiconductor materials. For example, InGaAs quantum wells may be replaced with AlInGaAs wells. Similarly, the barrier layers may comprise a variety of materials, such as AlGaAs or AlGaInAsP. It will be understood that the barrier layers may be comprised of a material having a lattice constant selected so that the barrier layers between quantum dot layers serve as strain compensation layers. In addition to quantum dot layers, in alternative embodiments, the active region may be comprised of quantum wells, quantum wires or combinations thereof.

The present invention has been discussed in detail in regards to laser structures grown on GaAs substrates. GaAs substrates have many advantages over other semiconductor substrates, such as a comparatively larger wafer sizes and higher manufacturing yields. However, embodiments of the present invention may be practiced on other types of substrates, such as InP substrates. Additionally, while molecular beam epitaxy has been described as a preferred fabrication technique, it will be understood that embodiments of the present invention may be practiced using other epitaxial techniques alternatively or additionally.

As a final example, in FIGS. 2-3, there is a single underlying structure and active region which is used by both the gain section and the absorber section. Forward biasing results in a gain section; reverse biasing results in an absorber section. In some embodiments, the isolation between adjacent gain sections is provided by proton implantation, with an isolation resistance on the order of several MΩ. One advantage of this approach is that different sections can be fabricated at the same time using the same semiconductor fabrication processes. However, this approach is not the only possible approach. For example, different sections of the laser could be fabricated at different times using different processes. The sections could also be separated by air gaps. For example, the gain section could be built up as one mesa and the absorber section as a separate mesa. Other approaches will be apparent.

What is claimed is:

1. An integrated mode-locked semiconductor laser for producing laser pulses comprising:
a horizontal laser cavity integrated on a semiconductor substrate, the laser cavity having an optical path;
a quantum-confined active region located along the optical path;
a gain section including a first portion of the quantum-confined active region;
an absorber section including a second portion of the quantum-confined active region, wherein a mode cross-section of the absorber section has a larger area than a mode cross-section of the gain section, and the gain section and/or the absorber section produce a loss modulation applied to laser pulses propagating around the laser cavity.

2. The laser of claim 1 wherein the mode cross-section of the absorber section is wider than the mode cross-section of the gain section.

3. The laser of claim 2 wherein the width of the mode cross-section transitions smoothly from the gain section to the absorber section.

4. The laser of claim 2 further comprising:
a tapered waveguide that transitions from a first width in the gain section to a second, wider width in the absorber section.

5. The laser of claim 2 further comprising:
a tapered ridge waveguide that transitions from a first width in the gain section to a second, wider width in the absorber section.

6. The laser of claim 1 wherein the mode cross-section of the absorber section has a greater height than the mode cross-section of the gain section.

7. The laser of claim 1 wherein:
the gain section includes an electrical contact for forward biasing the quantum-confined active region;
the absorber section includes an electrical contact for reverse biasing the quantum-confined active region; and
the gain section and the absorber section are a single monolithic structure but the gain section is electrically isolated from the absorber section.

8. The laser of claim 7 further comprising:
a proton-implanted barrier located between the gain section and the absorber section for electrically isolating the gain section from the absorber section.

9. The laser of claim 7 further comprising:
lower cladding layer(s), lower waveguide layer(s), quantum-confined active region layer(s) that form the quantum-confined active region, upper waveguide layer(s) and upper cladding layer(s); wherein the gain section includes the a first portion of the foregoing layers and the absorber section includes a second portion of the foregoing layers.

10. The laser of claim 1 wherein the integrated mode-locked semiconductor laser is passively mode-locked.

11. The laser of claim 10 wherein saturation of the quantum-confined active region of the absorber section produces the loss modulation.

12. The laser of claim 1 wherein the integrated mode-locked semiconductor laser is actively mode-locked.

13. The laser of claim 12 wherein the gain section further comprises:
an electrical contact for applying a periodically modulated electrical signal to forward bias the quantum-confined active region of the gain section, thus producing the loss modulation.

14. The laser of claim 12 further comprising:
a second gain section including an electrical contact and a third portion of the quantum-confined active region, the electrical contact for forward biasing the quantum-confined active region of the second gain section.

15. The laser of claim 12 wherein the absorber section further comprises:
an electrical contact for applying a periodically modulated electrical signal to reverse bias the quantum-confined active region of the absorber section, thus producing the loss modulation.

16. The laser of claim 1 wherein the horizontal laser cavity comprises two parallel planar mirrors.

17. The laser of claim 16 wherein the horizontal laser cavity comprises a semiconductor structure cleaved on two ends to form two parallel planar mirrors.

18. The laser of claim 17 wherein the two cleaved ends are coated with dielectric reflection coatings.

19. The laser of claim 1 wherein the quantum-confined active region comprises quantum well layers.

20. The laser of claim 1 wherein the quantum-confined active region comprises quantum wires.

21. The laser of claim 1 wherein the quantum-confined active region comprises quantum dots.

22. The laser of claim 21 wherein the semiconductor substrate is a GaAs substrate, and the quantum-confined active region comprises self-assembled InAs quantum dots in InGaAs quantum wells.

23. The laser of claim 1 wherein the substrate is a GaAs substrate.

24. The laser of claim 1 wherein the substrate is an InP substrate.

25. The laser of claim 1 wherein the substrate is a GaSb substrate.

26. The laser of claim 1 wherein the substrate is a GaN substrate.

27. The laser of claim 1 wherein the quantum-confined active region is constructed from the InGaAs materials system.

28. The laser of claim 1 wherein the quantum-confined active region is constructed from a materials system using at least two of the following elements: In, Ga, As, P, Al.

29. The laser of claim 1 wherein the quantum-confined active region is constructed from a materials system using Sb and at least one of the following elements: In, Ga, As, P, Al.

30. The laser of claim 1 wherein the integrated mode-locked semiconductor laser produces laser pulses in the 1060-1340 nm wavelength range.

31. A device for producing laser pulses, comprising:
a semiconductor substrate; and
a mode-locked semiconductor laser integrated on the semiconductor substrate, the mode-locked semiconductor laser comprising:
a laser cavity having an optical path;
a gain section located along the optical path;
an absorber section location along the optical path, wherein a mode cross section of the absorber section is larger than a mode cross section of the gain section; and
a quantum-confined active region located in the gain section and/or the absorber section.

32. The device of claim 31 wherein a mode cross-section of the absorber section has a larger area than a mode cross-section of the gain section.

33. The device of claim 31 wherein the mode cross-section of the absorber section is wider than the mode cross-section of the gain section.

34. The device of claim 33 further comprising:
a tapered waveguide that transitions from a first width in the gain section to a second, wider width in the absorber section.

35. The device of claim 31 wherein:
the gain section includes an electrical contact for forward biasing the quantum-confined active region;
the absorber section includes an electrical contact for reverse biasing the quantum-confined active region; and
the gain section and the absorber section are a single monolithic structure but the gain section is electrically isolated from the absorber section.

36. The device of claim 35 further comprising:
lower cladding layer(s), lower waveguide layer(s), quantum-confined active region layer(s) that form the quantum-confined active region, upper waveguide layer(s) and upper cladding layer(s); wherein the gain section includes the a first portion of the foregoing layers and the absorber section includes a second portion of the foregoing layers.

37. The device of claim 31 wherein the integrated mode-locked semiconductor laser is passively mode-locked.

38. The device of claim 31 wherein the integrated mode-locked semiconductor laser is actively mode-locked.

39. The device of claim 31 wherein the horizontal laser cavity comprises two parallel planar mirrors.

40. The device of claim 31 wherein the quantum-confined active region comprises quantum dots.
